(19) United States
(12) Patent Application Publication
(10) Pub. No.: US 2024/0332372 A1
(43) Pub. Date: Oct. 3, 2024

(54) NITRIDE SEMICONDUCTOR DEVICE

(71) Applicant: Panasonic Holdings Corporation, Osaka (JP)

(72) Inventors: Naohiro TSURUMI, Kyoto (JP); Naoki TORII, Osaka (JP); Daisuke SHIBATA, Kyoto (JP); Satoshi TAMURA, Osaka (JP)

(21) Appl. No.: 18/739,679

(22) Filed: Jun. 11, 2024

Related U.S. Application Data
(63) Continuation of application No. PCT/JP2022/028179, filed on Jul. 20, 2022.

(30) Foreign Application Priority Data
Dec. 27, 2021 (JP) 2021-212461

(51) Int. Cl. H01L 29/20; H01L 29/06; H01L 29/40; H01L 29/423; H01L 29/778

(52) U.S. Cl. CPC H01L 29/2003; H01L 29/0607; H01L 29/402; H01L 29/42316; H01L 29/7786

(57) ABSTRACT

A nitride semiconductor device includes a substrate, a first nitride semiconductor layer, a first high-resistance semiconductor layer, a first p-type nitride semiconductor layer, and a second high-resistance semiconductor layer that are arranged sequentially from a lower side; an electron mobility layer and an electron supply layer covering a first opening that penetrates through the second high-resistance semiconductor layer, the first p-type nitride semiconductor layer, and the first high-resistance semiconductor layer; a potential-fixing electrode that is disposed in contact with the first p-type nitride semiconductor layer; and an insulating film that covers a gate electrode and a source electrode. The insulating film is disposed along an inner surface of a groove portion that is disposed in an end portion of the nitride semiconductor device, and penetrates through the first p-type nitride semiconductor layer. The first high-resistance semiconductor layer is a high-resistance AlGaN layer.

### CROSS REFERENCE TO RELATED APPLICATIONS

This is a continuation application of PCT International Application No. PCT/JP2022/028179 filed on Jul. 20, 2022, designating the United States of America, which is based on and claims priority of Japanese Patent Application No. 2021-212461 filed on Dec. 27, 2021. The entire disclosures of the above-identified applications, including the specifications, drawings and claims are incorporated herein by reference in their entirety.

### FIELD

The present disclosure relates to a nitride semiconductor device.

### BACKGROUND

Nitride semiconductors typified by gallium nitride (GaN) are wide-bandgap semiconductors having a large bandgap, which have large dielectric breakdown electric fields and have a higher electron saturated drift rate than those of compound semiconductors such as gallium arsenide (GaAs) or silicon (Si) semiconductors. For example, the bandgaps of GaN and aluminum nitride (AlN) are 3.4 eV and 6.2 eV at room temperature, respectively. For this reason, power transistors using nitride semiconductors that are advantageous in an increase in output and an increase in breakdown voltage have been studied and developed. For example, Patent Literature (PTL) 1 and PTL 2 each disclose a vertical field effect transistor (FET) including a GaN-based semiconductor layer.

### CITATION LIST

### Patent Literature

PTL 1: WO 2021/070469
PTL 2: WO 2021/140898

### SUMMARY

### Technical Problem

However, the traditional semiconductor devices disclosed above can be improved upon.

The present disclosure provides a nitride semiconductor device having improved off properties.

### Solution to Problem

The nitride semiconductor device according to one aspect of the present disclosure includes a substrate; a first nitride semiconductor layer disposed above the substrate; a first high-resistance semiconductor layer that is disposed above the first nitride semiconductor layer and has a resistance higher than a resistance of the first nitride semiconductor layer; a first p-type nitride semiconductor layer disposed above the first high-resistance semiconductor layer; a second high-resistance semiconductor layer that is disposed above the first p-type nitride semiconductor layer and has a resistance higher than the resistance of the first nitride semiconductor layer; an electron mobility layer and an electron supply layer disposed sequentially from a lower side to cover a first opening and a top surface of the second high-resistance semiconductor layer, the first opening penetrating through the second high-resistance semiconductor layer, the first p-type nitride semiconductor layer, and the first high-resistance semiconductor layer and reaching the first nitride semiconductor layer; a gate electrode disposed above the electron supply layer to cover the first opening; a source electrode that is spaced from the gate electrode and is in contact with the electron supply layer; a potential-fixing electrode that is disposed in contact with the first p-type nitride semiconductor layer and is connected to the source electrode in a second opening that penetrates through the second high-resistance semiconductor layer and reaches the first p-type nitride semiconductor layer; a drain electrode disposed below the substrate; and an insulating film that covers the gate electrode and the source electrode. The insulting film is further disposed along an inner surface of a groove portion that is disposed in an end portion of the nitride semiconductor device, and penetrates through the first p-type nitride semiconductor layer and reaches the first high-resistance semiconductor layer. The first high-resistance semiconductor layer is a high-resistance AlGaN layer.

### Advantageous Effects

The present disclosure provides a nitride semiconductor device having improved off properties.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view of a nitride semiconductor device according to Embodiment 1.

FIG. 2 is a plan view of the nitride semiconductor device according to Embodiment 1.

FIG. 3 is a cross-sectional view of a nitride semiconductor device according to Embodiment 2.

FIG. 4 is a cross-sectional view of a nitride semiconductor device according to Embodiment 3.

FIG. 5 is a cross-sectional view of a nitride semiconductor device according to Embodiment 4.

### DESCRIPTION OF EMBODIMENTS

### Knowledge Forming Basis of the Present (Underlying Disclosure)

The present inventors have found that the traditional nitride semiconductor devices described in “Background” have the following problems.

In the nitride semiconductor device disclosed in PTL 1, a GaN layer having a high resistance and a p-type GaN layer disposed above the GaN layer are arranged between a source electrode and a drift layer. An improvement in breakdown voltage is attempted by disposing the GaN layer having a high resistance.

In the nitride semiconductor device disclosed in PTL 2, an undoped AlGaN layer and a p-type GaN layer disposed above the undoped AlGaN layer are arranged between a source electrode and a drift layer. In the undoped AlGaN layer, a two-dimensional electron gas is generated within the drift layer near the interface with the undoped AlGaN layer. This expands the current path in the traverse direction, thereby reducing the resistance during operation.

The present inventors have examined deposition of a groove portion penetrating through the p-type GaN layer in the device end portion in such a traditional nitride semiconductor device. By disposing the groove portion, the p-type GaN layer can be prevented from appearing in the end face, and thus the leakage current flowing in the end face can be suppressed.

In the nitride semiconductor device disclosed in PTL 1, however, it is difficult to etch the p-type GaN layer for forming the groove portion so that the remaining GaN layer having a high resistance has a uniform film thickness. Specifically, portions of microspikes are formed, in which the drift layer is locally etched. A leakage current between the p-type GaN layer and the drift layer may be caused through these portions of microspikes by voltage applied between the source electrode and the drain electrode when the device is off.

Since a high-resistance layer is not disposed in the nitride semiconductor device disclosed in PTL 2, the breakdown voltage may be reduced due to an increase in off-leakage during reverse conducting operation. Moreover, since the two-dimensional electron gas is present within the drift layer, an electric field is likely to concentrate on the end face of the groove portion, inducing a reduction in off properties.

Thus, those traditional nitride semiconductor devices have a problem of reduced off properties.

In contrast, the nitride semiconductor device according to one aspect of the present disclosure includes a substrate; a first nitride semiconductor layer disposed above the substrate; a first high-resistance semiconductor layer that is disposed above the first nitride semiconductor layer and has a resistance higher than a resistance of the first nitride semiconductor layer; a first p-type nitride semiconductor layer disposed above the first high-resistance semiconductor layer; a second high-resistance semiconductor layer that is disposed above the first p-type nitride semiconductor layer and has a resistance higher than the resistance of the first nitride semiconductor layer; an electron mobility layer and an electron supply layer disposed sequentially from a lower side to cover a first opening and a top surface of the second high-resistance semiconductor layer, the first opening penetrating through the second high-resistance semiconductor layer, the first p-type nitride semiconductor layer, and the first high-resistance semiconductor layer and reaching the first nitride semiconductor layer; a gate electrode disposed above the electron supply layer to cover the first opening; a source electrode that is spaced from the gate electrode and is in contact with the electron supply layer; a potential-fixing electrode that is disposed in contact with the first p-type nitride semiconductor layer and is connected to the source electrode in a second opening that penetrates through the second high-resistance semiconductor layer and reaches the first p-type nitride semiconductor layer; a drain electrode disposed below the substrate; and an insulating film that covers the gate electrode and the source electrode. The insulating film is further disposed along an inner surface of a groove portion that is disposed in an end portion of the nitride semiconductor device, and penetrates through the first p-type nitride semiconductor layer and reaches the first high-resistance semiconductor layer. The first high-resistance semiconductor layer is a high-resistance AlGaN layer.

In such a configuration, the high-resistance AlGaN layer is disposed between the source electrode and the first nitride semiconductor layer, and thus the breakdown voltage can be improved. Moreover, the high-resistance AlGaN layer functions as a stopper layer against etching for formation of the groove portion. For this reason, the high-resistance AlGaN layer can be left in a position corresponding to the bottom of the groove portion, and formation of a leakage current path such as portions of microspikes can be suppressed. Thus, a reduction in breakdown voltage of the device can be suppressed, improving the off properties.

Moreover, for example, the nitride semiconductor device according to one aspect of the present disclosure may include a second nitride semiconductor layer disposed between the first nitride semiconductor layer and the first high-resistance semiconductor layer. The second nitride semiconductor layer may be an undoped AlGaN layer.

In such a configuration, a two-dimensional electron gas is generated within the first nitride semiconductor layer near the interface with the undoped AlGaN layer. Since the current is likely to spread in the traverse direction within the first nitride semiconductor layer, the on-resistance can be reduced. To be noted, since the two-dimensional electron gas is also likely to spread near the groove portion within the first nitride semiconductor layer, an electric field is likely to concentrate on the end face of the groove portion. However, the high-resistance AlGaN layer disposed on the bottom of the groove portion enables the device to endure a high electric field, and the breakdown voltage can be improved. Thus, an improvement in off properties and a reduction in on-resistance can be satisfied at the same time.

When the nitride semiconductor layer is etched during formation of the groove portion, nitrogen is removed from the nitride semiconductor layer, causing N vacancies in the nitride semiconductor layer. In contrast, for example, the insulating film may contain at least Si and N.

The insulating film can terminate N vacancies in the nitride semiconductor layer, thus suppressing generation of current collapse.

Moreover, for example, the nitride semiconductor device according to one aspect of the present disclosure may include a second p-type nitride semiconductor layer disposed between the gate electrode and the electron supply layer.

In such a configuration, the carrier concentration immediately below the gate electrode can be reduced by the second p-type nitride semiconductor layer, and the threshold voltage of the FET can be shifted to the positive side. Thus, the transistor portion of the nitride semiconductor device can be operated as a normally-off type FET.

Moreover, for example, the nitride semiconductor device according to one aspect of the present disclosure may include a field plate disposed above the insulating film to project to the groove portion.

Such a configuration can relax the concentration of the electric field on the end portion, and can further improve the off properties.

Moreover, for example, the field plate may be electrically connected to the source electrode.

Such a configuration can further relax the concentration of the electric field on the end portion, and can further improve the off properties.

Hereinafter, embodiments will be specifically described with reference to the drawings.

The embodiments described below all illustrate general or specific examples. Numeric values, shapes, materials, components, arrangement positions of components and connection forms thereof, steps, order of steps, and the like shown in embodiments below are exemplary, and should not be construed as limitations to the present disclosure. Moreover, among the components of the embodiments below, the components not described in an independent claim will be described as optional components.

The drawings are schematic views, and are not necessarily precise illustrations. Accordingly, for example, the scale is not always consistent among the drawings. In the drawings, identical reference signs are given to substantially identical configurations, and duplications of descriptions thereof will be omitted or simplified.

In this specification, terms representing relations between entities, such as parallel or orthogonal, terms representing shapes of entities, such as rectangular or trapezoidal, and ranges of numeric values are not expressions indicating only their strict meanings, but are expressions containing substantially equivalent ranges, for example, differences of about several percent.

In this specification and the drawings, the x-axis, the y-axis, and the z-axis represent three axes in a three-dimensional orthogonal coordinate frame. When the shape of a substrate in planar view is a rectangular shape, the x-axis and the y-axis are a direction parallel to a first side of the rectangular shape and a direction parallel to a second side orthogonal to the first side, respectively. The z-axis is a thickness direction of the substrate. In this specification, the “thickness direction” of the substrate refers to a direction vertical to a main surface of the substrate. The thickness direction is identical to the stack direction of semiconductor layers, and is also referred to as “longitudinal direction”. Moreover, a direction parallel to the main surface of the substrate may be referred to as “traverse direction” in some cases.

The side of the substrate (positive side of the z-axis) on which the gate electrode and the source electrode are arranged is regarded as “above” or “upper side”, and the side of the substrate on which the drain electrode is disposed (negative side of the z-axis) is regarded as “below” or “lower side”.

In this specification, the terms “above” and “below” are used as terms defined by a relatively positional relation based on the stacking order in the stack configuration, but not those indicating an upper direction (vertically upper) and a lower direction (vertically lower) in absolute spatial recognition. The terms “above” and “below” are also applied not only in cases where two components are arranged with an interval and a different component is present between the two components, but also in cases where two components are arranged to be adjacent to and be in contact with each other.

In this specification, “in planar view” indicates viewing in a direction vertical to the main surface of the substrate of the nitride semiconductor device, namely, viewing the main surface of the substrate from its front.

In this specification, unless otherwise specified, ordinal numbers such as “first” and “second” do not mean the number or order of components, but are used to avoid confusion of similar components and distinguish those components.

In this specification, AlGaN represents ternary mixed crystal AlₓGa₁₋ₓN (where 0<x<1). Hereinafter, mulitinary mixed crystals are each abbreviated to an arrangement of symbols for constitutional elements, such as AlInN or GaInN. For example, AlₓGa_{1-x-y}In_{y}N (where 0<x<1, 0<y<1, and 0<x+y<1) as one example of the nitride semiconductor is abbreviated to AlGaInN.

### Embodiment 1

### [Outline]

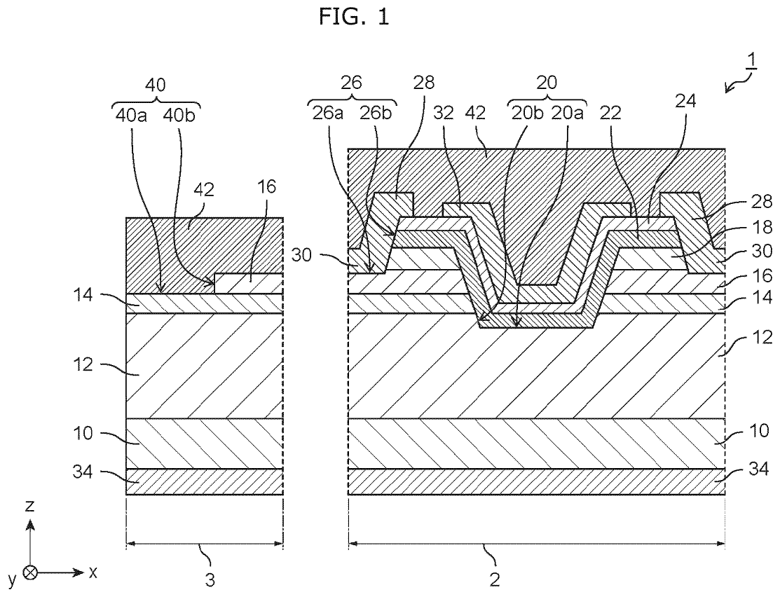

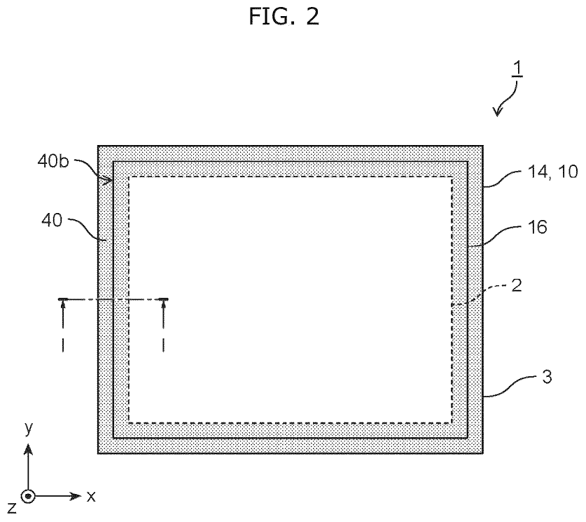

First, the outline of the nitride semiconductor device according to Embodiment 1 will be described with reference to FIGS. 1 and 2.

FIG. 1 is a cross-sectional view of nitride semiconductor device 1 according to the present embodiment. FIG. 2 is a plan view of nitride semiconductor device 1 according to the present embodiment. FIG. 1 represents the cross-section taken along line I-I in FIG. 2. FIG. 1 schematically illustrates transistor portion 2 separated from end portion 3.

As illustrated in FIG. 1, nitride semiconductor device 1 includes transistor portion 2 and end portion 3. Specifically, nitride semiconductor device 1 includes substrate 10, drift layer 12, first high-resistance semiconductor layer 14, p-type nitride semiconductor layer 16, second high-resistance semiconductor layer 18, gate opening 20, electron mobility layer 22, electron supply layer 24, source opening 26, source electrode 28, potential-fixing electrode 30, gate electrode 32, and drain electrode 34. Nitride semiconductor device 1 also includes groove portion 40 disposed in end portion 3, and insulating film 42 disposed across transistor portion 2 and end portion 3.

Transistor portion 2 is a region including an FET, in which the center of nitride semiconductor device 1 is included as illustrated in FIG. 2. Specifically, transistor portion 2 in planar view is a region where second high-resistance semiconductor layer 18, gate opening 20, electron mobility layer 22, electron supply layer 24, source electrode 28, or gate electrode 32 is disposed (see FIG. 1).

In FIG. 2, illustration of details of the components arranged in transistor portion 2 is omitted. As one example, source electrodes 28 having an elongated shape in one direction in planar view are arranged to form stripes, and gate electrode 32 and gate opening 20 are arranged between adjacent source electrodes 28. Alternatively, source electrodes 28 having a hexagonal shape in planar view may be spaced from each other to fill the plane.

End portion 3 is a region other than transistor portion 2, and is disposed like a ring to surround transistor portion 2. End portion 3 does not include second high-resistance semiconductor layer 18, gate opening 20, electron mobility layer 22, electron supply layer 24, source electrode 28, and gate electrode 32.

In the present embodiment, nitride semiconductor device 1 is a device having a stack structure of semiconductor layers each containing a nitride semiconductor such as GaN or AlGaN as the main component. Specifically, nitride semiconductor device 1 has a hetero-structure of an AlGaN film and a GaN film.

In the hetero-structure of the AlGaN film and the GaN film, a two-dimensional electron gas in a high concentration is generated at the hetero-interface due to spontaneous polarization or piezoelectric polarization on the (0001) plane. For this reason, a sheet carrier concentration of 1×10¹³ cm⁻² or more is obtained at the interface even in an undoped state.

Nitride semiconductor device 1 according to the present embodiment is a field effect transistor (FET) using the two-dimensional electron gas generated within electron mobility layer 22 as the channel. Specifically, nitride semiconductor device 1 is a so-called vertical FET.

Nitride semiconductor device 1 according to the present embodiment is a normally-off type FET. In nitride semiconductor device 1, for example, source electrode 28 is grounded (namely, the potential is 0 V), and a positive potential is given to drain electrode 34. The potential given to drain electrode 34 is 100 V or more and 1200 V or less, for example, although the potential is not limited thereto. When nitride semiconductor device 1 is off, 0 V or a negative potential (e.g., −5 V) is applied to gate electrode 32. When nitride semiconductor device 1 is on, a positive potential (e.g., +5 V) is applied to gate electrode 32. Nitride semiconductor device 1 may be a normally-on type FET.

### [Configuration of Transistor Portion]

Hereinafter, the configuration of transistor portion 2 in nitride semiconductor device 1 will be described with reference to FIG. 1.

Substrate 10 is made of a nitride semiconductor. Substrate 10 is, for example, a substrate made of n⁺-type GaN with a thickness of 300 μm and a donor concentration of 1×10¹⁸ cm⁻³. The top surface of substrate 10 approximately corresponds to the (0001) plane (c plane) of GaN.

The n-type, n⁺-type, n⁻-type, p-type, p⁺-type, and p⁻-type each indicate a conductivity type of a semiconductor. The n-type, n⁺-type, and n⁻-type are one examples of the first conductivity type of the nitride semiconductor. The p-type, p⁺-type, and p⁻-type are one examples of the second conductivity type having a polarity different from that of the first conductivity type.

Substrate 10 need not to be a nitride semiconductor substrate. For example, substrate 10 may be a silicon (Si) substrate, a silicon carbide (SiC) substrate, or a zinc oxide (ZnO) substrate.

Drift layer 12 is one example of the first nitride semiconductor layer disposed above substrate 10. For example, drift layer 12 is a film made of n⁻-type GaN with a thickness of 8 μm. Drift layer 12 is disposed in contact with the top surface of substrate 10. The donor concentration of drift layer 12 is lower than that of substrate 10, for example, 1×10¹⁵ cm⁻³ or more and 1×10¹⁷ cm⁻³ or less. Drift layer 12 may contain carbon (C). The carbon concentration in drift layer 12 is lower than that in first high-resistance semiconductor layer 14, for example, 1×10¹⁵ cm⁻³ or more and 2×10¹⁷ cm⁻³ or less.

First high-resistance semiconductor layer 14 is one example of the first high-resistance semiconductor layer disposed above drift layer 12. The resistance of first high-resistance semiconductor layer 14 is higher than that of drift layer 12. The thickness of first high-resistance semiconductor layer 14 is 200 nm, for example. First high-resistance semiconductor layer 14 is disposed in contact with the top surface of drift layer 12.

First high-resistance semiconductor layer 14 is a high-resistance AlGaN layer. The high-resistance AlGaN layer is a layer containing AlGaN as the main component and having a resistance higher than that of undoped AlGaN because it contains a predetermined element. The term “undoped” indicates that the nitride semiconductor is not substantially doped with a dopant which changes the polarity of the nitride semiconductor to the n-type or p-type, such as Si, oxygen (O), or magnesium (Mg).

Specifically, first high-resistance semiconductor layer 14 is an AlGaN layer containing carbon (C). The carbon concentration is, for example, 3×10¹⁷ cm⁻³ or more, and may be preferably 1×10¹⁸ cm⁻³ or more. First high-resistance semiconductor layer 14 may be formed by injecting ions of magnesium (Mg), iron (Fe), or boron (B) into AlGaN. Any ion species that can increase the resistance can be used in ion injection to obtain the same effect as above.

p-Type nitride semiconductor layer 16 is one example of the first p-type nitride semiconductor layer disposed above first high-resistance semiconductor layer 14. For example, p-type nitride semiconductor layer 16 is a film made of p⁻-type GaN with a thickness of 400 nm and a carrier concentration of 1×10¹⁷ cm⁻³. For example, p-type nitride semiconductor layer 16 contains magnesium (Mg) as a p-type impurity. p-Type nitride semiconductor layer 16 is disposed in contact with the top surface of first high-resistance semiconductor layer 14.

Second high-resistance semiconductor layer 18 is one example of the second high-resistance semiconductor layer disposed above p-type nitride semiconductor layer 16. The resistance of second high-resistance semiconductor layer 18 is higher than that of drift layer 12. Second high-resistance semiconductor layer 18 has a thickness of 200 nm, for example. Second high-resistance semiconductor layer 18 is disposed in contact with the top surface of p-type nitride semiconductor layer 16.

Second high-resistance semiconductor layer 18 is a high-resistance GaN layer. The high-resistance GaN layer is a layer containing GaN as the main component and having a resistance higher than that of undoped GaN because it contains a predetermined element. Specifically, second high-resistance semiconductor layer 18 is a GaN layer containing carbon (C). The carbon concentration is, for example, 3×10¹⁷ cm⁻³ or more, and may be preferably 1×10¹⁸ cm⁻³ or more.

Gate opening 20 is one example of the first opening that penetrates through second high-resistance semiconductor layer 18, p-type nitride semiconductor layer 16, and first high-resistance semiconductor layer 14 and reaches drift layer 12. As illustrated in FIG. 1, gate opening 20 has bottom 20a and side wall portion 20b. Bottom 20a corresponds to the top surface of drift layer 12, and is located on a side lower than the interface between first high-resistance semiconductor layer 14 and drift layer 12. Side wall portion 20b corresponds to the end faces of second high-resistance semiconductor layer 18, p-type nitride semiconductor layer 16, and first high-resistance semiconductor layer 14, and part of the top surface of drift layer 12. Side wall portion 20b of gate opening 20 is inclined to the main surface of substrate 10. For example, the cross-sectional shape of gate opening 20 is a reverse trapezoid, more specifically, a reverse isosceles trapezoid. The cross-sectional shape of gate opening 20 may be a rectangular shape.

Electron mobility layer 22 is disposed to cover the top surface of second high-resistance semiconductor layer 18 and gate opening 20. Specifically, electron mobility layer 22 is disposed in contact with the top surface of second high-resistance semiconductor layer 18, and side wall portion 20b and bottom 20a of gate opening 20. Electron mobility layer 22 is a first regrowth layer formed by regrowth of the nitride semiconductor after gate opening 20 is formed. Electron mobility layer 22 has a substantially uniform thickness, and is curved along the inner surface shape of gate opening 20. Electron mobility layer 22 is a film made of undoped GaN with a thickness of 100 nm, for example. Electron mobility layer 22 may be doped with Si or the like to be converted to the n-type.

An AlN layer having a thickness of about 1 nm as a second regrowth layer may be disposed between electron mobility layer 22 and electron supply layer 24. The AlN layer can suppress alloy scattering, and improve channel mobility. The AlN layer need not to be disposed. The AlN layer may be in direct contact with electron mobility layer 22 and electron supply layer 24. A two-dimensional electron gas (not illustrated) serving as a channel is generated within electron mobility layer 22 near the interface between the AlN layer and electron mobility layer 22.

Electron supply layer 24 is disposed above electron mobility layer 22. Specifically, electron supply layer 24 is disposed along the top surface of electron mobility layer 22. Electron supply layer 24 is a third regrowth layer formed by regrowth of the nitride semiconductor after gate opening 20 is formed. Electron supply layer 24 has a substantially uniform thickness, and is curved along the curve shape of the top surface of electron mobility layer 22. Electron supply layer 24 is a film made of AlGaN with a thickness of 50 nm, for example.

Source opening 26 is one example of the second opening that penetrates through second high-resistance semiconductor layer 18 in a position away from gate electrode 32 and reaches p-type nitride semiconductor layer 16. Specifically, source opening 26 penetrates through electron supply layer 24, electron mobility layer 22, and second high-resistance semiconductor layer 18 and reaches p-type nitride semiconductor layer 16.

As illustrated in FIG. 1, source opening 26 has bottom 26a and side wall portion 26b. Bottom 26a is the top surface of p-type nitride semiconductor layer 16, and is located on a side lower than the interface between p-type nitride semiconductor layer 16 and second high-resistance semiconductor layer 18. Side wall portion 26b corresponds to the end faces of electron supply layer 24, electron mobility layer 22, and second high-resistance semiconductor layer 18, and part of the top surface of p-type nitride semiconductor layer 16. Side wall portion 26b of source opening 26 is inclined to the main surface of substrate 10. For example, the cross-sectional shape of source opening 26 is a reverse trapezoid, more specifically, a reverse isosceles trapezoid. The cross-sectional shape of source opening 26 may be a rectangular shape.

Source electrode 28 is spaced from gate electrode 32, and is in contact with electron supply layer 24 and electron mobility layer 22. Source electrode 28 is disposed to cover bottom 26a and side wall portion 26b of source opening 26. Source electrode 28 is in direct contact with the two-dimensional electron gas within electron mobility layer 22 in side wall portion 26b of source opening 26.

Source electrode 28 is formed using a conductive material such as a metal. As the material for source electrode 28, a material that forms an ohmic contact with an n-type semiconductor can be used, and for example, titanium (Ti) or the like can be used. Source electrode 28 may have a stack structure of a Ti film and an Al film. The stack structure where the Al film is located on a side lower than the Ti film is represented by Ti/Al in this specification.

Fixed-potential electrode 30 is in contact with p-type nitride semiconductor layer 16 on bottom 26a of source opening 26. In the present embodiment, potential-fixing electrode 30 is electrically connected to source electrode 28. Specifically, potential-fixing electrode 30 is part of source electrode 28. Fixed-potential electrode 30 can be regarded as a portion in contact with bottom 26a of source opening 26 in source electrode 28. Fixed-potential electrode 30 is formed using the same material as that for source electrode 28.

Gate electrode 32 is disposed above electron supply layer 24 to cover gate opening 20. Gate electrode 32 is formed in contact with the top surface of electron supply layer 24 to have a substantially uniform thickness and be in a shape along the top surface of electron supply layer 24.

Gate electrode 32 is formed using a conductive material such as a metal. For example, gate electrode 32 is formed using Pd. As the material for gate electrode 32, a material that forms a Shottky contact with the n-type semiconductor can be used, and an Ni-based material, WSi, or Au can be used, for example.

Drain electrode 34 is disposed below substrate 10. Specifically, drain electrode 34 is disposed in contact with the bottom surface of substrate 10 (the surface opposite to the crystal growth surface). Drain electrode 34 is formed using a conductive material such as a metal. As in the material for source electrode 28, a material that forms an ohmic contact with the n-type semiconductor can be used for drain electrode 34, for example.

The nitride semiconductor layers can be formed by epitaxial growth such as Metal-Organic Vapor Phase Epitaxy (MOVPE). Specifically, drift layer 12, first high-resistance semiconductor layer 14, p-type nitride semiconductor layer 16, second high-resistance semiconductor layer 18, electron mobility layer 22, and electron supply layer 24 can be sequentially formed using a MOVPE apparatus. Drift layer 12, first high-resistance semiconductor layer 14, p-type nitride semiconductor layer 16, and second high-resistance semiconductor layer 18 are continuously formed in this order within the same chamber, for example. Subsequently, after gate opening 20 is formed, electron mobility layer 22 and electron supply layer 24 are continuously formed within the same chamber by crystal regrowth.

The p-type impurity and the impurity for increasing the resistance can be added to the respective layers by introducing an impurity element during crystal growth. Alternatively, after an undoped semiconductor layer is formed, an impurity may be added by ion injection.

Gate opening 20, source opening 26, and groove portion 40 are formed by photolithography and etching. Etching is dry etching, for example.

Source electrode 28, potential-fixing electrode 30, gate electrode 32, and drain electrode 34 are formed by forming a metal film by deposition or sputtering, and patterning the metal film in a predetermined shape. Patterning can be performed by photolithography and etching. Drain electrode 34 may be disposed on the entire bottom surface of substrate 10 without being patterned.

### [Configuration of End Portion]

Subsequently, the configuration of end portion 3 of nitride semiconductor device 1 according to the present embodiment will be described.

As illustrated in FIG. 1, end portion 3 does not include second high-resistance semiconductor layer 18, electron mobility layer 22, electron supply layer 24, source electrode 28, and gate electrode 32. For example, second high-resistance semiconductor layer 18, electron mobility layer 22, and electron supply layer 24 in end portion 3 are removed simultaneously when source opening 26 is formed.

End portion 3 includes groove portion 40. Groove portion 40 is an isolation trench for defining and separating transistor portion 2. Groove portion 40 penetrates through p-type nitride semiconductor layer 16 and reaches first high-resistance semiconductor layer 14. Part of p-type nitride semiconductor layer 16 is disposed in end portion 3. In other words, end portion 3 in planar view includes a region where p-type nitride semiconductor layer 16 is disposed, and a region where p-type nitride semiconductor layer 16 is not disposed (specifically, a region where groove portion 40 is disposed).

Groove portion 40 has bottom 40a and side wall portion 40b. In the present embodiment, groove portion 40 is a recessed portion having side wall portion 40b only on the side of transistor portion 2. In other words, bottom 40a of groove portion 40 connects to the end face of nitride semiconductor device 1. As illustrated in FIG. 2, groove portion 40 is disposed like a ring to surround transistor portion 2.

Bottom 40a of groove portion 40 is part of the top surface of first high-resistance semiconductor layer 14. Bottom 40a is parallel to the top surface of substrate 10, for example.

As illustrated in FIG. 1, groove portion 40 is formed to have a fixed opening area irrespective of the distance from substrate 10. Specifically, side wall portion 40b of groove portion 40 is vertical to bottom 40a. In other words, the cross-sectional shape of groove portion 40 is a rectangular shape. The cross-sectional shape of groove portion 40 may be a reverse trapezoid as in gate opening 20.

For example, groove portion 40 is formed by performing a dry etching step to form source opening 26, and then changing the etching mask, followed by dry etching. Alternatively, after source electrode 28 or potential-fixing electrode 30 is formed or after gate electrode 32 is formed, groove portion 40 may be formed by dry etching.

### [Main Characteristic Configuration and Effect]

Subsequently, the main characteristic configuration and effects of nitride semiconductor device 1 described above will be described.

In the present embodiment, first high-resistance semiconductor layer 14 is disposed between drift layer 12 and p-type nitride semiconductor layer 16. Specifically, by interposing first high-resistance semiconductor layer 14 between n-type GaN (drift layer 12) and p-type GaN (p-type nitride semiconductor layer 16) which constitute a parasitic pn bonding portion of a parasitic pn diode, a current is made between p-type nitride semiconductor layer 16 and drift layer 12. In short, the current path of the parasitic pn-junction diode can be blocked.

In the case where nitride semiconductor device 1 is off, such a configuration can suppress flow of a large current from source electrode 28 to drain electrode 34 even when the drain potential becomes lower than the source potential. Since a large current is difficult to flow in the parasitic pn diode during reverse conducting operation, a reduction in breakdown voltage attributed to the reverse conducting operation can be suppressed.

The potential of p-type nitride semiconductor layer 16 is fixed by potential-fixing electrode 30. Specifically, p-type nitride semiconductor layer 16 is fixed at the same potential as the potential (source potential) of source electrode 28. Thereby, carriers between p-type nitride semiconductor layer 16 and gate electrode 32 can be depleted, suppressing the drain-gate leakage current when the device is off. In other words, p-type nitride semiconductor layer 16 functions as a block layer which suppresses a leakage current flowing from drain electrode 34 to source electrode 28 without passing through the channel (two-dimensional electron gas within electron mobility layer 22).

Since groove portion 40 is disposed in end portion 3, p-type nitride semiconductor layer 16 can be spaced from the end face of nitride semiconductor device 1. Such a configuration can suppress generation of a leakage current along the end face of the device when it is off, thus increasing the breakdown voltage.

In the present embodiment, p-type nitride semiconductor layer 16 and first high-resistance semiconductor layer 14 are formed using different materials. Specifically, while p-type nitride semiconductor layer 16 is a p-type GaN layer, first high-resistance semiconductor layer 14 is an AlGaN layer to which carbon is added. The AlGaN layer functions as a stopper layer against dry etching of the GaN layer. In other words, when p-type nitride semiconductor layer 16 (GaN layer) is removed by dry etching, first high-resistance semiconductor layer 14 (AlGaN layer) is left without being removed. Since local openings and portions having a small film thickness are not formed in first high-resistance semiconductor layer 14, generation of a leakage current path between p-type nitride semiconductor layer 16 and n-type drift layer 12 can be suppressed. Thereby, generation of the leakage current when the device is off can be suppressed, increasing the breakdown voltage.

As described above, the off properties can be improved by nitride semiconductor device 1 according to the present embodiment.

Insulating film 42 is disposed across transistor portion 2 and end portion 3. Specifically, insulating film 42 is disposed to cover gate electrode 32 and source electrode 28 and disposed along the inner surfaces (bottom 40a and side wall portion 40b) of groove portion 40. For example, insulating film 42 is a protective film which covers substantially the entire region of nitride semiconductor device 1.

Insulating film 42 is formed using an insulative material. For example, insulating film 42 contains silicon (Si) and nitrogen (N). Thus, even when N vacancies are generated in the GaN layer due to nitrogen removed by dry etching, insulating film 42 can terminate the N vacancies. Thus, a reduction in film quality of the GaN layer can be suppressed, and generation of current collapse can be suppressed. Insulating film 42 need not always contain Si and N. For example, insulating film 42 is a monolayer of a silicon oxide film, a silicon nitride film, a silicon oxynitride film, or an aluminum oxide film or a stack structure thereof.

### Embodiment 2

Subsequently, Embodiment 2 will be described.

Unlike the nitride semiconductor device according to Embodiment 1, the nitride semiconductor device according to Embodiment 2 includes a semiconductor layer which forms a hetero-interface with drift layer 12. Hereinafter, differences from Embodiment 1 will be mainly described, and descriptions of configurations in common will be omitted or simplified.

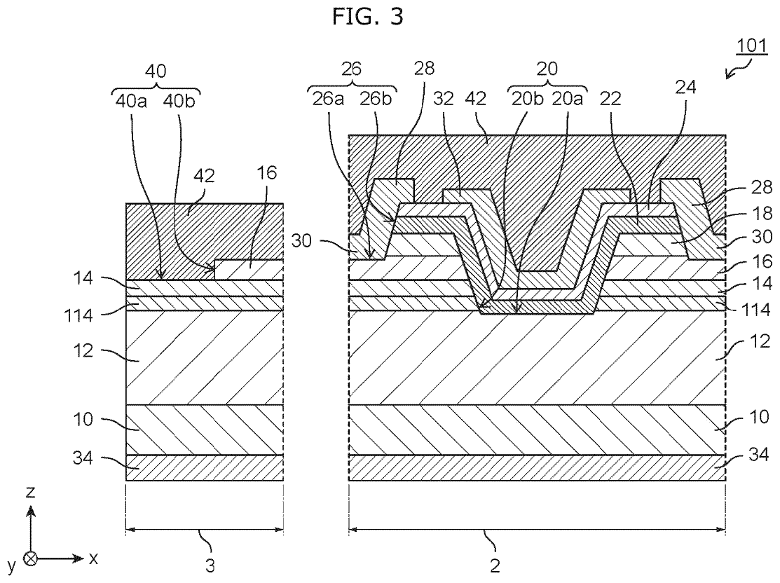

FIG. 3 is a cross-sectional view of nitride semiconductor device 101 according to the present embodiment. As illustrated in FIG. 3, nitride semiconductor device 101 includes electron supply layer 114 in addition to the configuration of nitride semiconductor device 1 illustrated in FIG. 1.

Electron supply layer 114 is one example of the second nitride semiconductor layer disposed between drift layer 12 and first high-resistance semiconductor layer 14. Electron supply layer 114 is a film made of undoped AlGaN with a thickness of 50 nm, for example. Electron supply layer 114 is formed by MOVPE subsequent to the formation of drift layer 12.

Electron supply layer 114 is disposed in contact with the top surface of drift layer 12 to form a hetero-interface of AlGaN/GaN between electron supply layer 114 and drift layer 12. Thereby, a two-dimensional electron gas is generated within drift layer 12 near the interface with electron supply layer 114.

In other words, in nitride semiconductor device 101, electron supply device 114 is formed to cause the two-dimensional electron gas to extend from the vicinity of bottom 20a of gate opening 20 in the traverse direction (specifically, a direction parallel to the top surface of substrate 10) within drift layer 12. For this reason, electrons which move through the two-dimensional electron gas within electron mobility layer 22 (channel) are likely to pass through the two-dimensional electron gas within drift layer 12 near bottom 20a and spread in the traverse direction. For this reason, not only the portion located immediately below bottom 20a within drift layer 12, but also portions located outside the portion (outside bottom 20a in planar view) are also available as a current flowing path. Such a configuration can facilitate diffusion of the source-drain current in a wide region within drift layer 12. This can reduce the resistance value when nitride semiconductor device 101 operates.

Since the two-dimensional electron gas within drift layer 12 also spreads to the vicinity of groove portion 40, an electric field is likely to concentrate on the end face of groove portion 40. However, because first high-resistance semiconductor layer 14 is disposed on bottom 40a of groove portion 40, groove portion 40 can endure a high electric field, improving the breakdown voltage. Thus, nitride semiconductor device 101 according to the present embodiment can satisfy both of an improvement in off properties and a reduction in on-resistance.

### Embodiment 3

Subsequently, Embodiment 3 will be described.

Unlike the nitride semiconductor device according to Embodiment 1, the nitride semiconductor device according to Embodiment 3 includes a p-type nitride semiconductor layer between the gate electrode and the electron mobility layer. Hereinafter, differences from Embodiment 1 will be mainly described, and descriptions of configurations in common will be omitted or simplified.

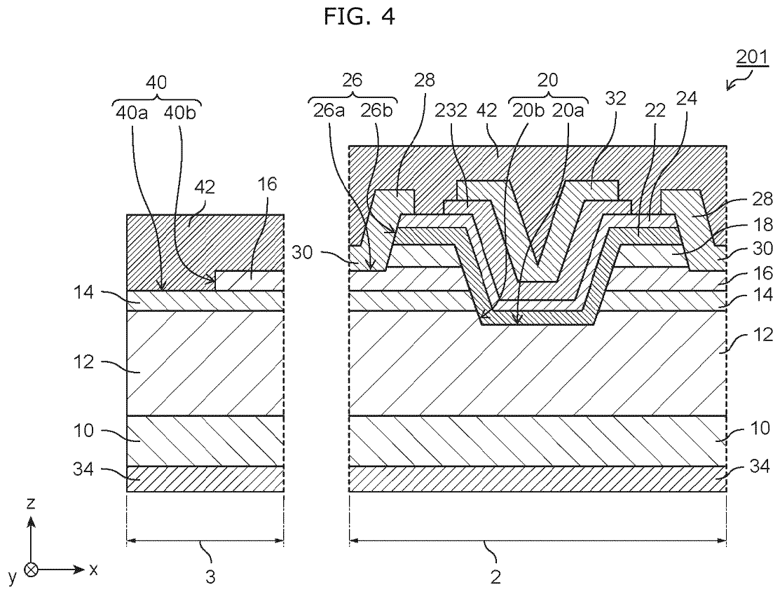

FIG. 4 is a cross-sectional view of nitride semiconductor device 201 according to the present embodiment. As illustrated in FIG. 4, nitride semiconductor device 201 includes p-type nitride semiconductor layer 232 in addition to the configuration of nitride semiconductor device 1 illustrated in FIG. 1.

As illustrated in FIG. 4, p-type nitride semiconductor layer 232 is one example of the second p-type nitride semiconductor layer disposed between gate electrode 32 and electron supply layer 24. p-Type nitride semiconductor layer 232 is in contact with the top surface of electron supply layer 24 and the bottom surface of gate electrode 32.

For example, p-type nitride semiconductor layer 232 is a nitride semiconductor layer made of p-type AlGaN with a thickness of 100 nm and a carrier concentration of 1×10¹⁷ cm⁻³. p-Type nitride semiconductor layer 232 is formed by forming a film by MOVPE subsequent to the formation of electron supply layer 24, and then patterning the film.

In the present embodiment, the potential of the conduction band end in the channel portion is lifted by p-type nitride semiconductor layer 232. For this reason, the threshold voltage of nitride semiconductor device 201 can be increased. In short, transistor portion 2 of nitride semiconductor device 201 can be operated as a normally-off type FET.

Instead of p-type nitride semiconductor layer 232, a layer formed using an insulative material such as silicon nitride (SiN) or silicon oxide (SiO₂) may be disposed. In short, any material which has the effect of lifting the potential of the channel can be used without limitation.

As in Embodiment 2, nitride semiconductor device 201 may include electron supply layer 114.

### Embodiment 4

Subsequently, Embodiment 4 will be described.

Unlike the nitride semiconductor device according to Embodiment 1, the nitride semiconductor device according to Embodiment 4 includes a field plate. Hereinafter, differences from Embodiment 1 will be mainly described, and descriptions of configurations in common will be omitted or simplified.

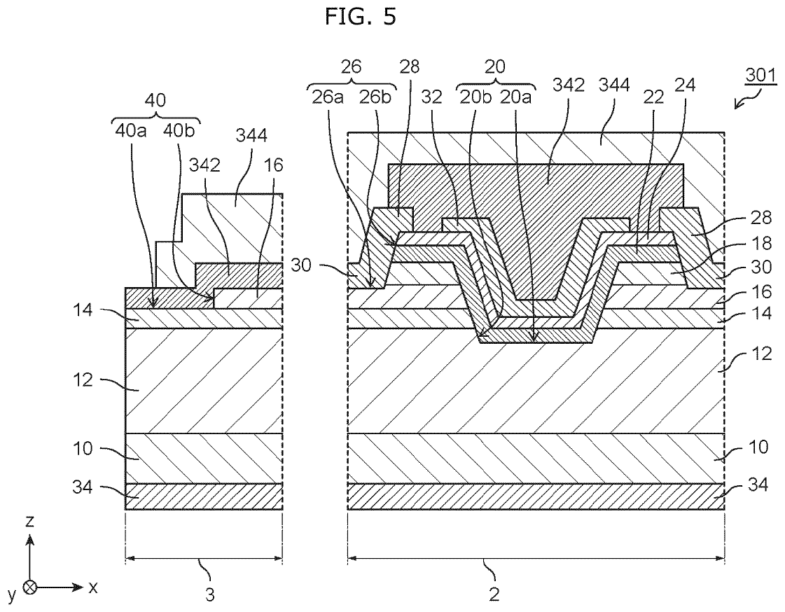

FIG. 5 is a cross-sectional view of nitride semiconductor device 301 according to the present embodiment. As illustrated in FIG. 5, nitride semiconductor device 301 includes field plate 344 in addition to the configuration of nitride semiconductor device 1 illustrated in FIG. 1. Nitride semiconductor device 301 also includes insulating film 342 instead of insulating film 42.

Insulating film 342 is disposed along the inner surface of groove portion 40. Specifically, insulating film 342 is disposed to electrically insulate field plate 344 from the components other than source electrode 28 (specifically, gate electrode 32, electron supply layer 24, p-type nitride semiconductor layer 16, first high-resistance semiconductor layer 14, and drift layer 12). For example, insulating film 342 is formed by forming a film across the entire top surface after gate electrode 32 and groove portion 40 are formed, and then patterning the film to expose at least part of source electrode 28. In other words, a contact hole for electrically connecting source electrode 28 to field plate 344 is formed in insulating film 342. Insulating film 342 can be formed using the same material as that for insulating film 42, for example.

Field plate 344 is disposed above insulating film 342 to project to groove portion 40. In other words, field plate 344 in planar view overlaps bottom 40a of groove portion 40.

Field plate 344 is formed using a conductive material such as a metal. For example, the same material as that for source electrode 28 can be used as the material for field plate 344. In the present embodiment, field plate 344 is electrically connected to source electrode 28. In other words, the same potential as that fed to source electrode 28 is fed to field plate 344.

In end portion 3, the electric field in the off state of the device is likely to concentrate on the intersecting portion of bottom 40a and side wall portion 40b in groove portion 40, that is, the corner of groove portion 40. Since field plate 344 is disposed to project to groove portion 40, part of the electric field concentrating on the intersecting portion of bottom 40a and side wall portion 40b can be dispersed to the projected portion of field plate 344. Since the pn junction including etching damage is present near the intersecting portion of bottom 40a and side wall portion 40b, the off properties of nitride semiconductor device 301 can be improved by relaxing the concentration of the electric field on the pn junction.

In the present embodiment, an example where field plate 344 is electrically connected to source electrode 28 has been illustrated, but any other configuration can be used. Field plate 344 may be insulated from source electrode 28, or the same potential as that for source electrode 28 or a different potential may be separately fed. In this case, the contact hole for electrically connecting source electrode 28 to field plate 344 is not disposed in insulating film 342.

As in Embodiment 2, nitride semiconductor device 301 may include electron supply layer 114. As in Embodiment 3, nitride semiconductor device 301 may include p-type nitride semiconductor layer 232.

### OTHER EMBODIMENTS

As above, the nitride semiconductor devices according to one or more aspects have been described based on the embodiments, but the present disclosure is not limited to these embodiments. A variety of modifications of the present embodiments conceived by persons skilled in the art and embodiments constituted by combinations of the components in different embodiments are also included in the scope of the present disclosure without departing the gist of the present disclosure.

For example, an example where potential-fixing electrode 30 is part of source electrode 28 has been illustrated in the above embodiment, any other configuration can be used. Potential-fixing electrode 30 and source electrode 28 may be physically spaced from each other. In this case, potential-fixing electrode 30 and source electrode 28 can be electrically connected by field plate 344 disposed above insulating film 342. Moreover, potential-fixing electrode 30 may be formed using a material different from that for source electrode 28.

For example, a material to be in ohmic contact with p-type nitride semiconductor layer 16 can be used as the material for potential-fixing electrode 30. For example, palladium (Pd), nickel (Ni), gold (Au), or tungsten silicide (WSi) can be used. Since these are identical to the material used for gate electrode 32, gate electrode 32 and potential-fixing electrode 30 can be formed in the same step.

For example, source electrode 28 need not to be disposed within source opening 26. For example, source electrode 28 is disposed on the top surface of electron supply layer 24, and need not to be in contact with electron mobility layer 22. In this case, source opening 26 is an opening for potential-fixing electrode 30 to contact p-type nitride semiconductor layer 16, and is disposed in a position spaced from source electrode 28.

For example, drift layer 12 may have a graded structure in which the impurity concentration (donor concentration) is gradually reduced from the side of substrate 10 to the side of first high-resistance semiconductor layer 14. The donor concentration may be controlled by Si serving as a donor, or may be controlled by carbon serving as an acceptor which compensates for Si. Alternatively, drift layer 12 may be configured of a plurality of nitride semiconductor layers having different impurity concentrations.

For example, end portion 3 need not include the end face of nitride semiconductor device 1. End portion 3 is a portion for separating transistor portion 2 from another device. Another element may be disposed in a region adjacent to transistor portion 2 with end portion 3 interposed therebetween. For example, another element is a pn diode using the pn junction between drift layer 12 and p-type nitride semiconductor layer 16. In this case, nitride semiconductor device 1 includes transistor portion 2, end portion 3, and a pn diode.

The embodiments described above can be subjected to a variety of modifications, replacements, additions, and omissions within the scope defined in CLAIMS or its equivalents.

### INDUSTRIAL APPLICABILITY

The present disclosure can be used as a nitride semiconductor device having improved off properties, and can be used in power devices used in power supply circuits for consumer products, for example.

1. A nitride semiconductor device comprising:
a substrate;
a first nitride semiconductor layer disposed above the substrate;
a first high-resistance semiconductor layer that is disposed above the first nitride semiconductor layer and has a resistance higher than a resistance of the first nitride semiconductor layer;
a first p-type nitride semiconductor layer disposed above the first high-resistance semiconductor layer;
a second high-resistance semiconductor layer that is disposed above the first p-type nitride semiconductor layer and has a resistance higher than the resistance of the first nitride semiconductor layer;
an electron mobility layer and an electron supply layer disposed sequentially from a lower side to cover a first opening and a top surface of the second high-resistance semiconductor layer, the first opening penetrating through the second high-resistance semiconductor layer, the first p-type nitride semiconductor layer, and the first high-resistance semiconductor layer and reaching the first nitride semiconductor layer;
a gate electrode disposed above the electron supply layer to cover the first opening;
a source electrode that is spaced from the gate electrode and is in contact with the electron supply layer;
a potential-fixing electrode that is disposed in contact with the first p-type nitride semiconductor layer and is connected to the source electrode in a second opening that penetrates through the second high-resistance semiconductor layer and reaches the first p-type nitride semiconductor layer;
a drain electrode disposed below the substrate; and
an insulating film that covers the gate electrode and the source electrode,
wherein the insulating film is further disposed along an inner surface of a groove portion that is disposed in an end portion of the nitride semiconductor device, and penetrates through the first p-type nitride semiconductor layer and reaches the first high-resistance semiconductor layer; and
the first high-resistance semiconductor layer is a high-resistance AlGaN layer.

2. The nitride semiconductor device according to claim 1, comprising:
a second nitride semiconductor layer disposed between the first nitride semiconductor layer and the first high-resistance semiconductor layer,
wherein the second nitride semiconductor layer is an undoped AlGaN layer.

3. The nitride semiconductor device according to claim 2,
wherein the high-resistance AlGaN layer has a resistance higher than a resistance of the undoped AlGaN layer.

4. The nitride semiconductor device according to claim 1,
wherein the insulating film contains at least Si and N.

5. The nitride semiconductor device according to claim 1, comprising:
a second p-type nitride semiconductor layer disposed between the gate electrode and the electron supply layer.

6. The nitride semiconductor device according to claim 1, comprising:
a field plate disposed above the insulating film to project to the groove portion.

7. The nitride semiconductor device according to claim 6,
wherein the field plate is electrically connected to the source electrode.
